(19) United States
(12) Patent Application Publication
(10) Pub. No.: US 2024/0407228 A1
(43) Pub. Date: Dec. 5, 2024

(54) DISPLAY DEVICE AND MANUFACTURING METHOD OF DISPLAY DEVICE

(71) Applicant: Japan Display Inc., Tokyo (JP)

(72) Inventors: Noriyuki HIRATA, Tokyo (JP); Hirofumi MIZUKOSHI, Tokyo (JP); Hiraaki KOKAME, Tokyo (JP)

(73) Assignee: Japan Display Inc., Tokyo (JP)

(21) Appl. No.: 18/669,573

(22) Filed: May 21, 2024

(30) Foreign Application Priority Data
May 29, 2023 (JP) 2023-088024

(51) Int. Cl. H10K 59/80; H10K 71/60

(52) U.S. Cl. CPC H10K 59/871; H10K 71/60

(57) ABSTRACT

According to one embodiment, a manufacturing method of a display device includes preparing a processing substrate by forming a lower electrode, forming an inorganic insulating layer, and forming a partition including a lower portion and an upper portion, forming an organic layer including a light emitting layer, forming an upper electrode, forming a cap layer, forming a first sealing layer, and forming a resin layer. The process of forming the organic layer, the upper electrode and the cap layer is an evaporation process using the partition as a mask in a vacuum environment. The process of forming the resin layer includes a process of applying a resinous material in an air atmosphere.

### CROSS-REFERENCE TO RELATED APPLICATION

This application is based upon and claims the benefit of priority from Japanese Patent Application No. 2023-088024, filed May 29, 2023, the entire contents of which are incorporated herein by reference.

### FIELD

Embodiments described herein relate generally to a display device and a manufacturing method of a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

The reduction in the manufacturing cost of display devices is required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a diagram showing a configuration example of a display element 20.

FIG. 5 is a diagram for explaining the outline of a manufacturing device.

FIG. 6A is a diagram showing a configuration example of the evaporation device 100 shown in FIG. 5.

FIG. 6B is a diagram showing another configuration example of the evaporation device 100 shown in FIG. 5.

FIG. 7 is a flowchart for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

### DETAILED DESCRIPTION

Embodiments described herein aim to provide a display device and a manufacturing method of a display device such that the manufacturing cost can be reduced.

In general, according to one embodiment, a manufacturing method of a display device comprises preparing a processing substrate by forming a lower electrode above a substrate, forming an inorganic insulating layer having an aperture which overlaps the lower electrode, and forming a partition including a lower portion located on the inorganic insulating layer and an upper portion which is located on the lower portion and protrudes from a side surface of the lower portion, forming an organic layer including a light emitting layer on the lower electrode in the aperture, forming an upper electrode on the organic layer, forming a cap layer on the upper electrode, forming a first sealing layer which covers the cap layer and the partition, and forming a resin layer which covers the first sealing layer. The process of forming the organic layer, the upper electrode and the cap layer is an evaporation process using the partition as a mask in a vacuum environment. The process of forming the resin layer includes a process of applying a resinous material in an air atmosphere.

According to another embodiment, a display device comprises a substrate, a lower electrode provided above the substrate, an inorganic insulating layer having an aperture which overlaps the lower electrode, an organic layer provided on the lower electrode in the aperture and including a light emitting layer, an upper electrode provided on the organic layer, a cap layer provided on the upper electrode, a partition which has a lower portion provided on the inorganic insulating layer, being in contact with the upper electrode and formed of a conductive material and an upper portion provided on the lower portion and protruding from a side surface of the lower portion, and surrounds the organic layer, the upper electrode and the cap layer, and a first sealing layer which is provided on the cap layer surrounded by the partition, is in contact with the side surface of the partition and is formed of an inorganic insulating material. The first sealing layer extends to an upper side of the partition and is spaced apart from the upper portion of the partition.

According to yet another embodiment, a manufacturing method of a display device comprises preparing a processing substrate by forming a lower electrode above a substrate, forming an inorganic insulating layer having an aperture which overlaps the lower electrode, and forming a partition which includes a lower portion located on the inorganic insulating layer and an upper portion located on the lower portion and protruding from a side surface of the lower portion, conveying the processing substrate to a first evaporation chamber, and forming an organic layer including a first light emitting layer on the lower electrode in the aperture, conveying the processing substrate without deposition of a material for forming a second light emitting layer which is different from the first light emitting layer in a second evaporation chamber for forming the second light emitting layer, conveying the processing substrate without deposition of a material for forming a third light emitting layer which is different from the first light emitting layer and the second light emitting layer in a third evaporation chamber for forming the third light emitting layer, forming an upper electrode on the organic layer, forming a cap layer on the upper electrode, forming a first sealing layer which covers the cap layer and the partition, and forming a resin layer which covers the first sealing layer. The process of forming the resin layer includes a process of applying a resinous material in an air atmosphere.

The embodiments can provide a display device and a manufacturing method of a display device such that the manufacturing cost can be reduced.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as “on” or “above”.

The display device of the embodiment is an organic electroluminescent display device comprising an organic light emitting diode (OLED) as a display element, and could be mounted on a television, a personal computer, a vehicle-mounted device, a tablet, a smartphone, a mobile phone, etc.

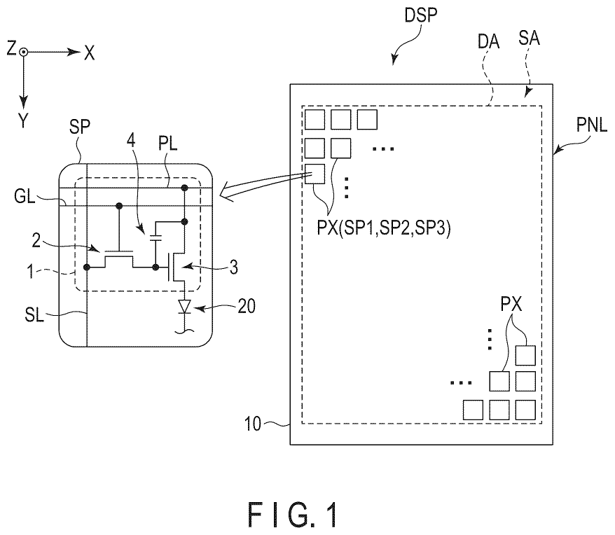

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4 etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

Although not described in detail, a terminal for connecting an IC chip and a flexible printed circuit is provided in the surrounding area SA.

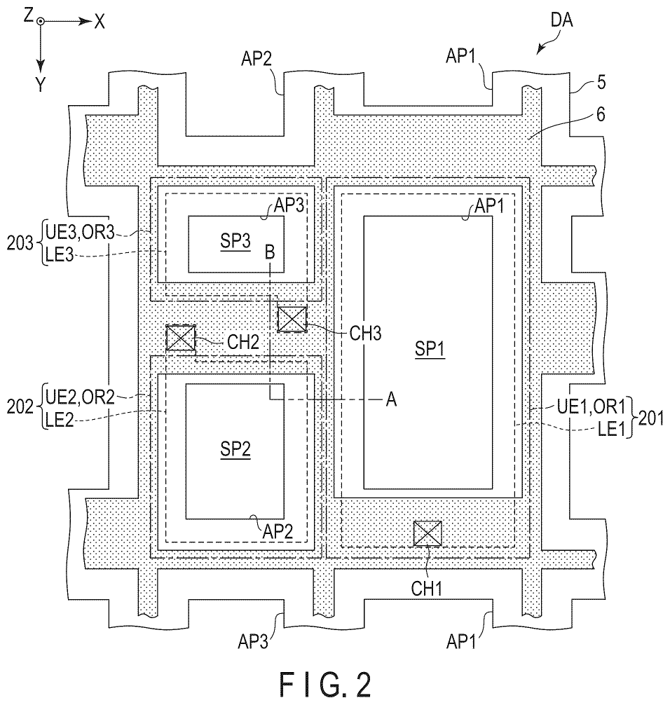

FIG. 2 is a diagram showing an example of the layout of subpixels SP1, SP2 and SP3.

In the example of FIG. 2, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5.

Subpixels SP1, SP2 and SP3 comprise display elements 201, 202 and 203, respectively, as the display elements 20.

The display element 201 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The display element 201 comprising the lower electrode LE1, the organic layer OR1 and the upper electrode UE1 is surrounded by the partition 6 in plan view. The peripheral portion of each of the organic layer OR1 and the upper electrode UE1 overlaps the inorganic insulating layer 5 in plan view. The organic layer OR1 includes a light emitting layer which emits light in, for example, a blue wavelength range.

The display element 202 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The display element 202 comprising the lower electrode LE2, the organic layer OR2 and the upper electrode UE2 is surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element 203 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The display element 203 comprising the lower electrode LE3, the organic layer OR3 and the upper electrode UE3 is surrounded by the partition 6 in plan view. The peripheral portion of each of the organic layer OR3 and the upper electrode UE3 overlaps the inorganic insulating layer 5 in plan view. The organic layer OR3 includes a light emitting layer which emits light in, for example, a red wavelength range.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

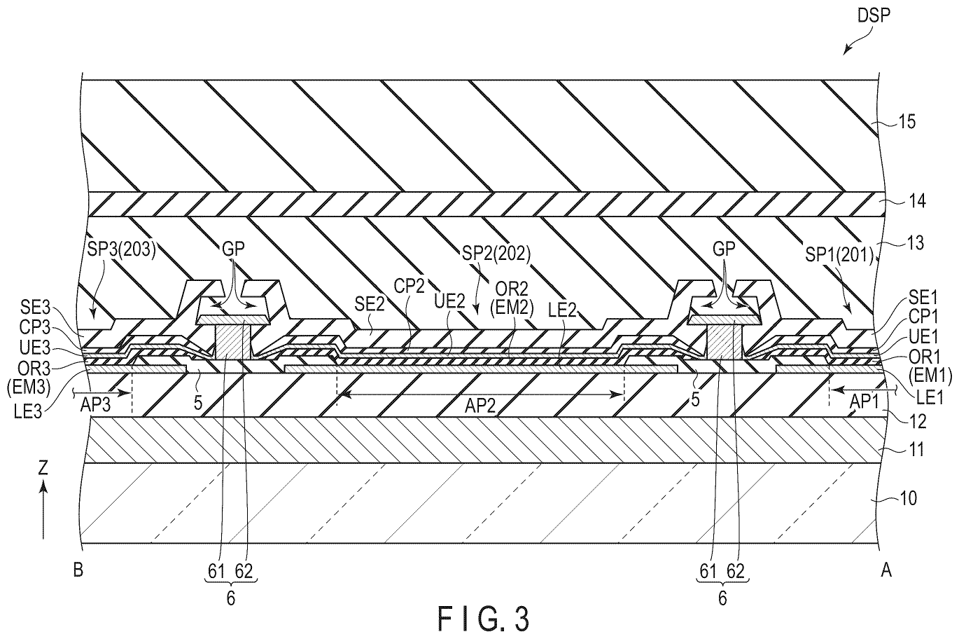

FIG. 3 is a schematic cross-sectional view of the display device DSP along the A-B line of FIG. 2.

A circuit layer 11 is provided on the substrate 10. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The insulating layer 12 is covered with the inorganic insulating layer 5 between, of the lower electrodes LE1, LE2 and LE3, the lower electrodes which are adjacent to each other. The lower electrodes LE1, LE2 and LE3 are connected to the pixel circuits 1 of subpixels SP1, SP2 and SP3, respectively, through the contact holes provided in the insulating layer 12. It should be noted that, although the contact holes of the insulating layer 12 are omitted in FIG. 3, the contact holes correspond to the contact holes CH1, CH2 and CH3 of FIG. 2.

The partition 6 includes a conductive lower portion (stem) 61 provided on the inorganic insulating layer 5 and an upper portion (shade) 62 provided on the lower portion 61. The lower portion 61 of the partition 6 shown on the right side of the figure is located between the aperture AP1 and the aperture AP2. The lower portion 61 of the partition 6 shown on the left side of the figure is located between the aperture AP2 and the aperture AP3. The upper portion 62 has a width greater than that of the lower portion 61. The both end portions of the upper portion 62 protrude relative to the side surfaces of the lower portion 61. This shape of the partition 6 is called an overhang shape.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example of FIG. 3, subpixel SP1 has a cap layer CP1 and a sealing layer SE1. Subpixel SP2 has a cap layer CP2 and a sealing layer SE2. Subpixel SP3 has a cap layer CP3 and a sealing layer SE3. The cap layers CP1, CP2 and CP3 function as optical adjustment layers which improve the extraction efficiency of the light emitted from the organic layers OR1, OR2 and OR3, respectively.

The cap layer CP1 is provided on the upper electrode UE1.

The cap layer CP2 is provided on the upper electrode UE2.

The cap layer CP3 is provided on the upper electrode UE3.

The sealing layer SE1 is provided on the cap layer CP1, is in contact with the partition 6 and continuously covers the members of subpixel SP1.

The sealing layer SE2 is provided on the cap layer CP2, is in contact with the partition 6 and continuously covers the members of subpixel SP2.

The sealing layer SE3 is provided on the cap layer CP3, is in contact with the partition 6 and continuously covers the members of subpixel SP3.

All of the sealing layers SE1, SE2 and SE3 extend to the upper side of the partition 6 and are spaced apart from the upper portion 62 of the partition 6. Thus, a gap GP is defined between each of the sealing layers SE1, SE2 and SE3 and the upper portion 62. The end portions of the sealing layers SE1, SE2 and SE3 are spaced apart from the upper portion 62. In other words, the gap GP is open under the end portion of each of the sealing layers SE1, SE2 and SE3.

It should be noted that each of the organic layer OR1, the upper electrode UE1 and the cap layer CP1 may be partly located on the partition 6 around subpixel SP1. However, these portions are spaced apart from, of the organic layer OR1, the upper electrode UE1 and the cap layer CP1, the portions located in the aperture AP1 (the portions constituting the display element 201).

Similarly, each of the organic layer OR2, the upper electrode UE2 and the cap layer CP2 may be partly located on the partition 6 around subpixel SP2. However, these portions are spaced apart from, of the organic layer OR2, the upper electrode UE2 and the cap layer CP2, the portions located in the aperture AP2 (the portions constituting the display element 202).

Similarly, each of the organic layer OR3, the upper electrode UE3 and the cap layer CP3 may be partly located on the partition 6 around subpixel SP3. However, these portions are spaced apart from, of the organic layer OR3, the upper electrode UE3 and the cap layer CP3, the portions located in the aperture AP3 (the portions constituting the display element 203).

The end portions of the sealing layers SE1, SE2 and SE3 are located above the partition 6. In the example of FIG. 3, the end portions of the sealing layers SE1 and SE2 located above the partition 6 between subpixels SP1 and SP2 are spaced apart from each other. The end portions of the sealing layers SE2 and SE3 located above the partition 6 between subpixels SP2 and SP3 are spaced apart from each other.

The sealing layers SE1, SE2 and SE3 are covered with a resin layer 13. Each of the gap GP surrounded by the upper portion 62 of the partition 6 and the sealing layer SE1, the gap GP surrounded by the upper portion 62 and the sealing layer SE2 and the gap GP surrounded by the upper portion 62 and the sealing layer SE3 is filled with the resin layer 13. In some cases, a cavity could be present in part of each gap GP as the gap GP is not completely filled with the resin layer 13.

The resin layer 13 is covered with a sealing layer 14.

The sealing layer 14 is covered with an overcoat layer 15.

Each of the inorganic insulating layer 5, the sealing layers SE1, SE2 and SE3 and the sealing layer 14 is formed of, for example, an inorganic insulating material such as silicon nitride (SiNx), silicon oxide (SiOx), silicon oxynitride (SiON) or aluminum oxide (Al₂O₃).

The resin layer 13 and the overcoat layer 15 are formed of the same resinous material.

The lower portion 61 of the partition 6 is formed of a conductive material and is electrically connected to the upper electrodes UE1, UE2 and UE3. The upper portion 62 of the partition 6 is formed of, for example, a conductive material. However, the upper portion 62 may be formed of an insulating material. The lower portion 61 is formed of a material which is different from that of the upper portion 62.

For example, each of the lower electrodes LE1, LE2 and LE3 is a multilayer body including a transparent electrode formed of an oxide conductive material such as indium tin oxide (ITO) and a metal electrode formed of a metal material such as silver.

The organic layer OR1 includes a light emitting layer EM1. The organic layer OR2 includes a light emitting layer EM2. The organic layer OR3 includes a light emitting layer EM3. The light emitting layer EM1, the light emitting layer EM2 and the light emitting layer EM3 are formed of materials which are different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other. It should be noted that at least one of the cap layers CP1, CP2 and CP3 may be omitted.

In the above configuration example, for example, the sealing layer SE1 corresponds to a first sealing layer, and the sealing layer 14 corresponds to a second sealing layer.

Now, this specification explains a configuration example of the display element 20.

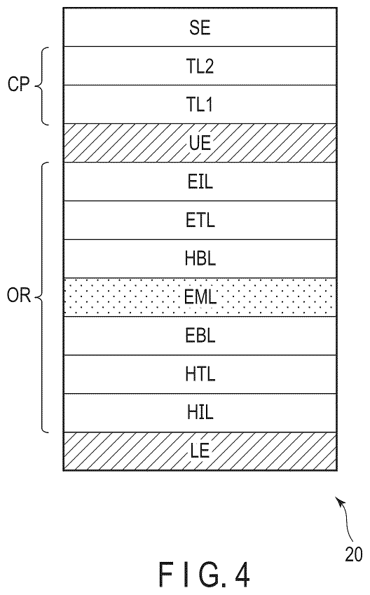

FIG. 4 is a diagram showing a configuration example of the display element 20.

The display element 20 shown in FIG. 4 could correspond to any one of the display elements 201, 202 and 203 described above.

Here, this specification explains an example in which a lower electrode LE corresponds to an anode and an upper electrode UE corresponds to a cathode.

The display element 20 comprises an organic layer OR (OR1, OR2 or OR3) between a lower electrode LE (LE1, LE2 or LE3) and an upper electrode UE (UE1, UE2 or UE3).

In the organic layer OR, a hole injection layer HIL, a hole transport layer HTL, an electron blocking layer EBL, a light emitting layer EML, a hole blocking layer HBL, an electron transport layer ETL and an electron injection layer EIL are stacked in this order.

It should be noted that the organic layer OR may include, in addition to the functional layers described above, other functional layers such as a carrier generation layer as needed, or at least one of the above functional layers may be omitted.

The light emitting layer EML corresponds to one of the light emitting layers EM1, EM2 and EM3 shown in FIG. 3.

A cap layer CP (CP1, CP2 or CP3) includes a first transparent layer TL1 and a second transparent layer TL2. The first transparent layer TL1 is provided on the upper electrode UE. The first transparent layer TL1 is a high-refractive layer having a refractive index which is higher than that of the upper electrode UE. The second transparent layer TL2 is provided on the first transparent layer TL1. The second transparent layer TL2 is a low-refractive layer having a refractive index which is less than that of the first transparent layer TL1. A sealing layer SE (SE1, SE2 or SE3) is provided on the second transparent layer TL2. It should be noted that the cap layer CP may be omitted.

It should be noted that the configuration of the organic layer OR is not limited to the configuration in which the organic layer OR comprises the light emitting layer EML consisting of a single layer as shown in the figure. The organic layer OR may comprise a plurality of light emitting layers.

Now, this specification explains the outline of a device for manufacturing the display device DSP.

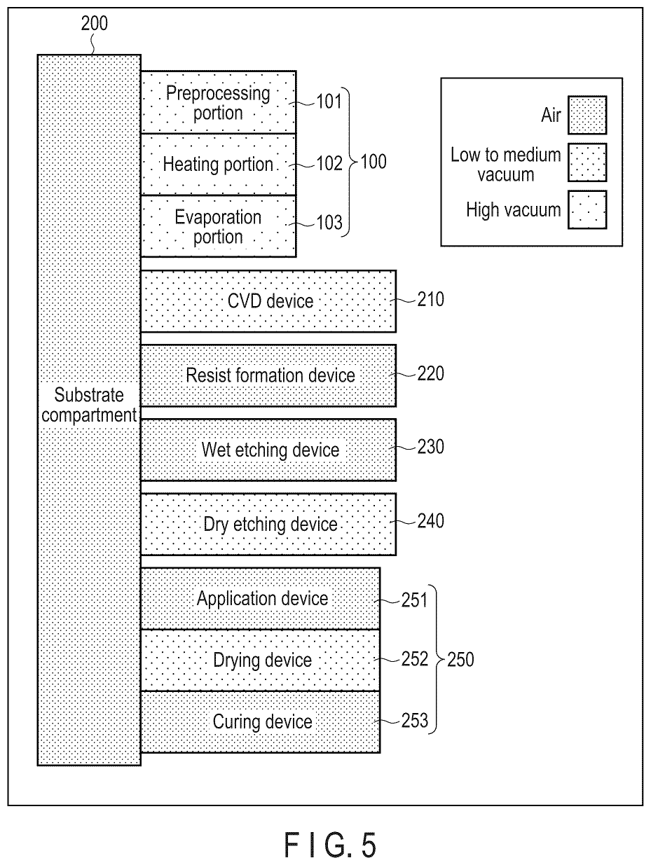

FIG. 5 is a diagram for explaining the outline of a manufacturing device.

A plurality of processing substrates are accommodated in a substrate compartment 200 in an air atmosphere. Here, each processing substrate is a mother substrate for a display device and comprises a plurality of panel portions on a large substrate. Each panel portion is extracted by dividing each processing substrate. Each of the extracted panel portions corresponds to the display panel PNL shown in FIG. 1 and comprises the display area DA and the surrounding area SA.

An in-line evaporation device 100 comprises a preprocessing portion 101, a heating portion 102 and an evaporation portion 103. The evaporation device 100 is configured to form an evaporation layer on a processing substrate in a high vacuum environment as described later.

A chemical vapor deposition (CVD) device 210 is configured to form the sealing layers SE1, SE2 and SE3 and the sealing layer 14 by depositing an inorganic insulating material (for example, silicon nitride) on a processing substrate in a vacuum environment. It should be noted that the degree of vacuum of the CVD device 210 is less than that of the evaporation device 100 in some cases.

A resist formation device 220 is configured to form a resist having a predetermined shape on the sealing layers SE1, SE2 and SE3 in an air atmosphere.

A wet etching device 230 is configured to remove part of an evaporation layer using a resist as a mask in an air atmosphere.

A dry etching device 240 is configured to remove part of an evaporation layer, part of the sealing layers SE1, SE2 and SE3 and part of the sealing layer 14 using a resist as a mask in a vacuum environment. It should be noted that the degree of vacuum of the dry etching device 240 is less than that of the evaporation device 100 in some cases.

A resin formation device 250 is configured to form the resin layer 13 and the overcoat layer 15. The resin formation device 250 comprises an application device 251, a drying device 252 and a curing device 253. The application device 251 is configured to apply a resinous material in an air environment. The drying device 252 is configured to dry a resinous material in a low vacuum environment where the pressure is reduced compared to an air atmosphere. It should be noted that the drying device 252 may be omitted. The curing device 253 is configured to perform the curing process of a resinous material. For example, when the resinous material is an ultraviolet curing resinous material, the curing device 253 is configured to irradiate the resinous material with ultraviolet rays.

Each of the evaporation device 100, the CVD device 210, the resist formation device 220, the wet etching device 230, the dry etching device 240 and the resin formation device 250 is connected to the substrate compartment 200 via a conveyance mechanism which is not described in detail.

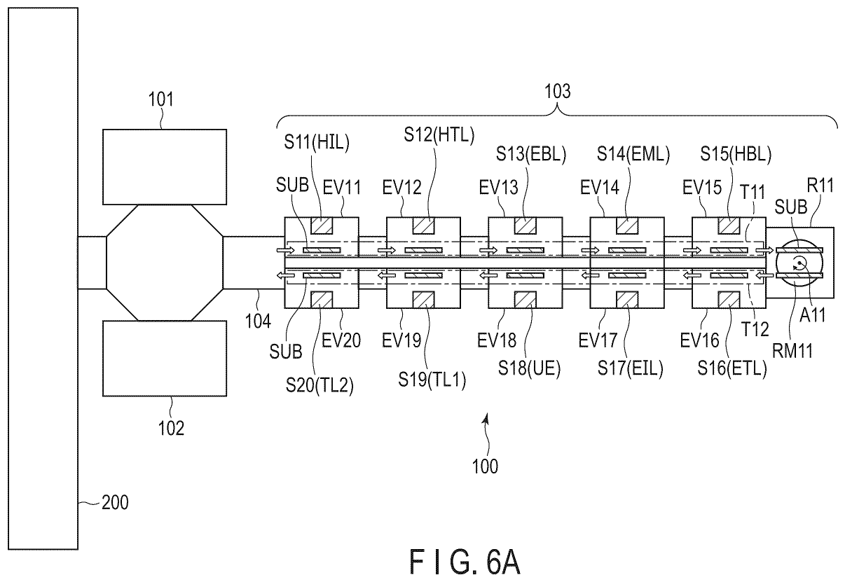

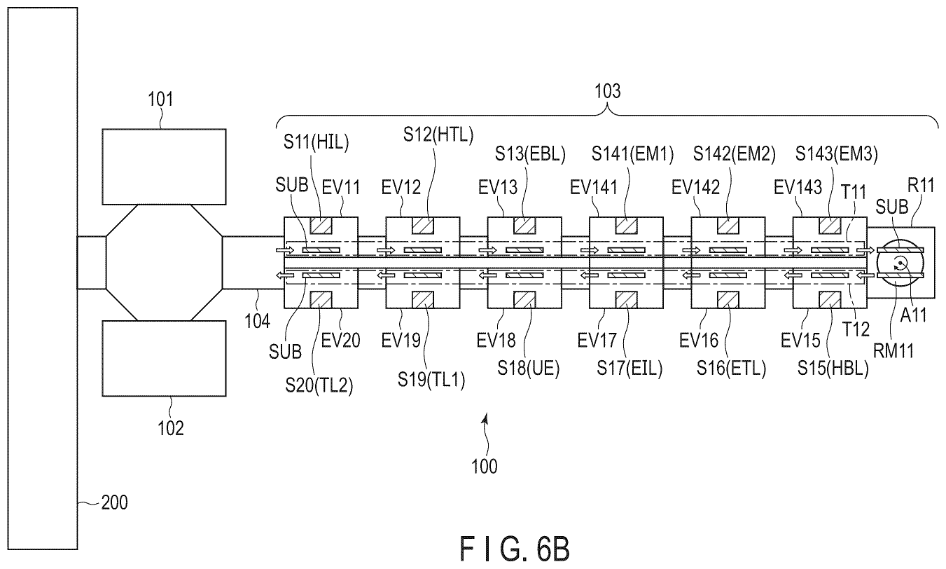

FIG. 6A is a diagram showing a configuration example of the evaporation device 100 shown in FIG. 5.

For example, the evaporation device 100 is applied in the process of successively forming the organic layer OR, upper electrode UE and cap layer CP shown in FIG. 4. A processing substrate SUB which is supposed to be carried in the evaporation device 100 comprises the circuit layer 11, the insulating layer 12, the lower electrodes LE1, LE2 and LE3, the inorganic insulating layer 5 and the partition 6 on the substrate 10.

The evaporation device 100 comprises the preprocessing portion 101, the heating portion 102 and the evaporation portion 103. Although not described in detail, the evaporation device 100 is connected to the substrate compartment 200 via the conveyance mechanism. The evaporation device 100 comprises a posture change portion 104 as part of the conveyance mechanism.

The preprocessing portion 101 comprises a mechanism which performs various preprocesses such as a plasma process for the processing substrate SUB which was carried in. The heating portion 102 comprises a mechanism which performs a heating process for the processing substrate SUB.

The posture change portion 104 comprises a mechanism which changes the posture of the processing substrate SUB, a mechanism which secures the processing substrate SUB to a dedicated carrier by an electrostatic chuck, a mechanism which detaches the processing substrate SUB from the carrier by releasing the securing applied by the electrostatic chuck, etc. For example, the posture of the processing substrate SUB which is carried in the preprocessing portion 101 and the heating portion 102 is a horizontal posture. The posture of the processing substrate SUB which was carried out of the preprocessing portion 101 and the heating portion 102 is changed from a horizontal posture to a perpendicular posture in the posture change portion 104. The posture of the processing substrate SUB which is carried in the evaporation portion 103 is a perpendicular posture. The posture of the processing substrate SUB which was carried out of the evaporation portion 103 is changed from a perpendicular posture to a horizontal posture in the posture change portion 104.

The evaporation portion 103 comprises a plurality of evaporation chambers EV11 to EV20 and a rotation chamber R11. The preprocessing portion 101, the heating portion 102, the posture change portion 104, the evaporation chambers EV11 to EV20 and the rotation chamber R11 are connected to each other and are maintained as a high vacuum.

The evaporation chambers EV11 to EV15 are arranged in a line. The evaporation chamber EV11 is connected to the posture change portion 104. The evaporation chamber EV15 is connected to the rotation chamber R11. A conveyance path T11 is provided over the evaporation chambers EV11 to EV15.

The evaporation chambers EV16 to EV20 are arranged in a line. The evaporation chamber EV16 is connected to the rotation chamber R11. The evaporation chamber EV20 is connected to the posture change portion 104. A conveyance path T12 is provided over the evaporation chambers EV16 to EV20.

The evaporation chamber EV11 comprises an evaporation source S11. The evaporation source S11 is configured to emit a material for forming the hole injection layer HIL to the conveyance path T11.

The evaporation chamber EV12 comprises an evaporation source S12. The evaporation source S12 is configured to emit a material for forming the hole transport layer HTL to the conveyance path T11.

The evaporation chamber EV13 comprises an evaporation source S13. The evaporation source S13 is configured to emit a material for forming the electron blocking layer EBL to the conveyance path T11.

The evaporation chamber EV14 comprises an evaporation source S14. The evaporation source S14 is configured to emit a material for forming the light emitting layer EML to the conveyance path T11.

The evaporation chamber EV15 comprises an evaporation source S15. The evaporation source S15 is configured to emit a material for forming the hole blocking layer HBL to the conveyance path T11.

The evaporation chamber EV16 comprises an evaporation source S16. The evaporation source S16 is configured to emit a material for forming the electron transport layer ETL to the conveyance path T12.

The evaporation chamber EV17 comprises an evaporation source S17. The evaporation source S17 is configured to emit a material for forming the electron injection layer EIL to the conveyance path T12.

The evaporation chamber EV18 comprises an evaporation source S18. The evaporation source S18 is configured to emit a material for forming the upper electrode UE to the conveyance path T12.

The evaporation chamber EV19 comprises an evaporation source S19. The evaporation source S19 is configured to emit a material for forming the first transparent layer TL1 to the conveyance path T12.

The evaporation chamber EV20 comprises an evaporation source S20. The evaporation source S20 is configured to emit a material for forming the second transparent layer TL2 to the conveyance path T12.

The rotation chamber R11 is configured to convey the processing substrate SUB which is carried out of the conveyance path T11 to the conveyance path T12. The rotation chamber R11 comprises a rotation mechanism RM11. The rotation mechanism RM11 is configured to hold the processing substrate SUB which is carried in the rotation chamber R11 via the conveyance path T11 and rotate around a rotation axis A11.

It should be noted that the configuration of the evaporation device 100 is not limited to the example shown in the figure.

FIG. 6B is a diagram showing another configuration example of the evaporation device 100 shown in FIG. 5.

The configuration example shown in FIG. 6B is different from the configuration example shown in FIG. 6A in respect that an evaporation chamber for forming each of the light emitting layers EM1, EM2 and EM3 is provided.

In the evaporation portion 103 of the evaporation device 100, the evaporation chambers EV11, EV12, EV13, EV141, EV142 and EV143 are arranged in a line. The evaporation chamber EV11 is connected to the posture change portion 104. The evaporation chamber EV143 is connected to the rotation chamber R11.

The evaporation chambers EV15 to EV20 are arranged in a line. The evaporation chamber EV15 is connected to the rotation chamber R11. The evaporation chamber EV20 is connected to the posture change portion 104.

The evaporation source S11 of the evaporation chamber EV11 is configured to emit a material for forming the hole injection layer HIL.

The evaporation source S12 of the evaporation chamber EV12 is configured to emit a material for forming the hole transport layer HTL.

The evaporation source S13 of the evaporation chamber EV13 is configured to emit a material for forming the electron blocking layer EBL.

The evaporation source S141 of the evaporation chamber EV141 is configured to emit a material for forming the light emitting layer EM1.

The evaporation source S142 of the evaporation chamber EV142 is configured to emit a material for forming the light emitting layer EM2.

The evaporation source S143 of the evaporation chamber EV143 is configured to emit a material for forming the light emitting layer EM3.

The materials emitted from the evaporation sources S141, S142 and S143 are light emitting materials which emit different colors.

The evaporation source S15 of the evaporation chamber EV15 is configured to emit a material for forming the hole blocking layer HBL.

The evaporation source S16 of the evaporation chamber EV16 is configured to emit a material for forming the electron transport layer ETL.

The evaporation source S17 of the evaporation chamber EV17 is configured to emit a material for forming the electron injection layer EIL.

The evaporation source S18 of the evaporation chamber EV18 is configured to emit a material for forming the upper electrode UE.

The evaporation source S19 of the evaporation chamber EV19 is configured to emit a material for forming the first transparent layer TL1.

The evaporation source S20 of the evaporation chamber EV20 is configured to emit a material for forming the second transparent layer TL2.

When the display element 201 is formed in this evaporation device 100, the materials are deposited in series in the evaporation chambers EV11, EV12, EV13 and EV141 while the processing substrate SUB is conveyed in a perpendicular posture. Subsequently, the processing substrate SUB is conveyed without the deposition of the materials in the evaporation chambers EV142 and EV143. Subsequently, the materials are deposited in series in the evaporation chambers EB15 to EV20.

When the display element 202 is formed, the materials are deposited in series in the evaporation chambers EV11, EV12 and EV13 while the processing substrate SUB is conveyed in a perpendicular posture. Subsequently, the processing substrate SUB is conveyed without the deposition of the material in the evaporation chamber EV141. Subsequently, the material is deposited in the evaporation chamber EV142. Subsequently, the processing substrate SUB is conveyed without the deposition of the material in the evaporation chamber EV143. Subsequently, the materials are deposited in series in the evaporation chambers EV15 to EV20.

When the display element 203 is formed, the materials are deposited in series in the evaporation chambers EV11, EV12 and EV13 while the processing substrate SUB is conveyed in a perpendicular posture. Subsequently, the processing substrate SUB is conveyed without the deposition of the materials in the evaporation chambers EV141 and EV142. Subsequently, the materials are deposited in series in the evaporation chambers EV143 and EV15 to EV20.

In each of the configuration examples shown in FIG. 6A and FIG. 6B, the evaporation portion 103 comprises the rotation chamber R11 and is configured to turn back the processing substrate SUB. However, the configuration is not limited to this example.

The evaporation device 103 may be configured to convey the processing substrate SUB in a single direction by omitting the rotation chamber R11. In this case, for example, in the configuration example shown in FIG. 6A, the evaporation chambers EV11, EV12, EV13, EV14, EV15, EV16, EV17, EV18, EV19 and EV20 are arranged in this order in a single direction. In the configuration example shown in FIG. 6B, the evaporation chambers EV11, EV12, EV13, EV141, EV142, EV143, EV15, EV16, EV17, EV18, EV19 and EV20 are arranged in this order in a single direction.

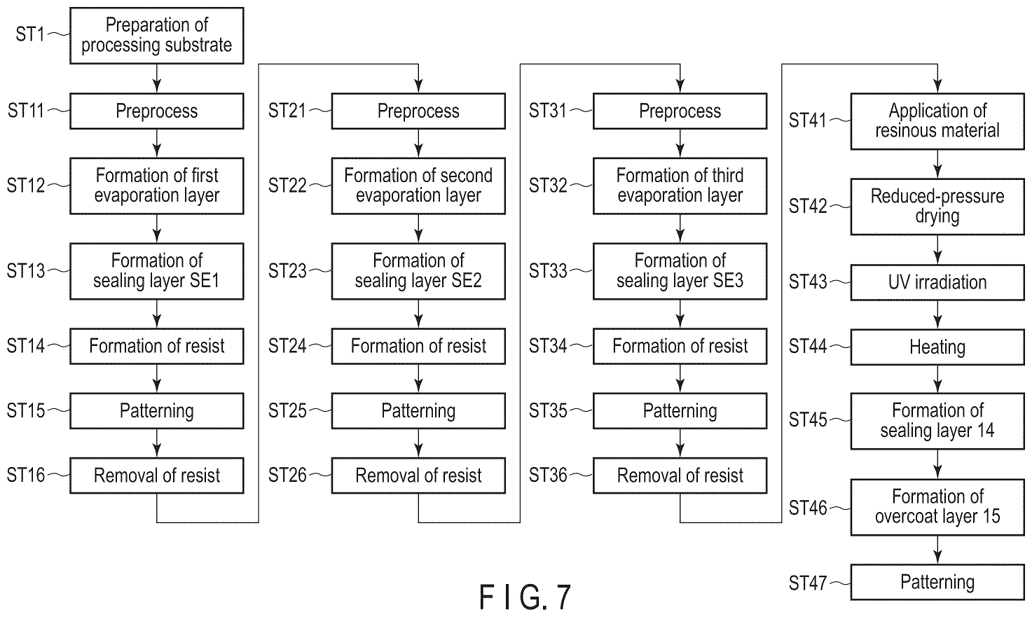

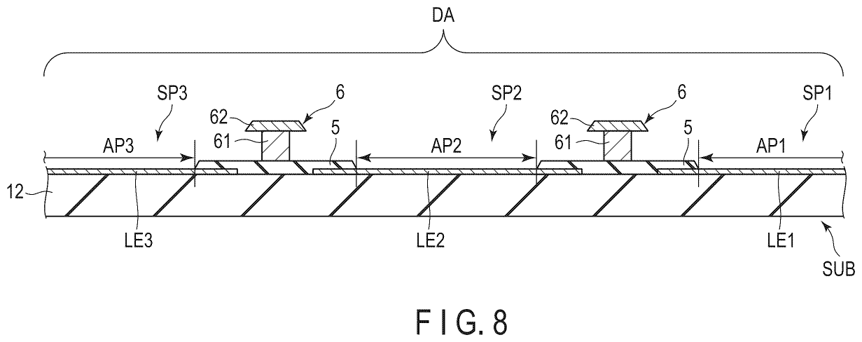

Now, this specification explains the manufacturing method of the display device DSP with reference to the flowchart shown in FIG. 7 and each of the cross-sectional views shown in FIG. 8 to FIG. 14. In FIG. 8 to FIG. 14, the illustration of the lower side of the insulating layer 12 is omitted.

First, a processing substrate SUB is prepared (ST1). The process of preparing the processing substrate SUB includes the process of forming the lower electrode LE1 of subpixel SP1, the lower electrode LE2 of subpixel SP2 and the lower electrode LE3 of subpixel SP3 on the insulating layer 12, the process of forming the inorganic insulating layer 5 having the apertures AP1, AP2 and AP3 overlapping the lower electrodes LE1, LE2 and LE3, respectively, and the process of forming the partition 6 having the lower portion 61 located on the inorganic insulating layer 5 and the upper portion 62 located on the lower portion 61 and protruding from the side surfaces of the lower portion 61. It should be noted that the partition 6 may be formed after the formation of the inorganic insulating layer 5 having the apertures AP1, AP2 and AP3, or the apertures AP1, AP2 and AP3 may be formed after the formation of the partition 6.

FIG. 8 shows the section of the prepared processing substrate SUB.

Subsequently, the display element 201 is formed.

First, the processing substrate SUB is carried in the evaporation device 100, and a predetermined process is performed for the processing substrate SUB in the preprocessing portion 101 (ST11). Subsequently, a heating process is performed for the processing substrate SUB in the heating portion 102 depending on the need. The processing substrate SUB is changed to a perpendicular posture in the posture change portion 104. The processing substrate SUB is carried in the evaporation portion 103.

Subsequently, a first evaporation layer is formed on the processing substrate SUB by performing vapor deposition using the partition 6 as a mask in the evaporation portion 103 (ST12). Specifically, the hole injection layer HIL is formed on the lower electrode LE1 in the evaporation chamber EV11. The hole transport layer HTL is formed on the hole injection layer HIL in the evaporation chamber EV12. The electron blocking layer EBL is formed on the hole transport layer HTL in the evaporation chamber EV13. The light emitting layer EML is formed on the electron blocking layer EBL in the evaporation chamber EV14. The hole blocking layer HBL is formed on the light emitting layer EML in the evaporation chamber EV15. The electron transport layer ETL is formed on the hole blocking layer HBL in the evaporation chamber EV16. The electron injection layer EIL is formed on the electron transport layer ETL in the evaporation chamber EV17. By this process, the organic layer OR1 including the light emitting layer EM1 is formed on the lower electrode LE1. Subsequently, the upper electrode UE1 is formed on the electron injection layer EIL in the evaporation chamber EV18. By this process, the upper electrode UE1 is formed on the organic layer OR1. Subsequently, the first transparent layer TL1 is formed on the upper electrode UE1 in the evaporation chamber EV19. The second transparent layer TL2 is formed on the first transparent layer TL1 in the evaporation chamber EV20. By this process, the cap layer CP1 is formed on the upper electrode UE1.

The organic layer OR1, the upper electrode UE1 and the cap layer CP1 correspond to the first evaporation layer and are successively formed in a vacuum environment in the evaporation device 100.

Subsequently, the sealing layer SE1 is formed on the first evaporation layer (ST13). Specifically, the processing substrate SUB is carried out of the evaporation portion 103. The processing substrate SUB is changed to a horizontal posture in the posture change portion 104. The processing substrate SUB is carried in the CVD device 210. An inorganic insulating material is deposited on the processing substrate SUB in the CVD device 210. By this process, the sealing layer SE1 which continuously covers the cap layer CP1 and the partition 6 is formed.

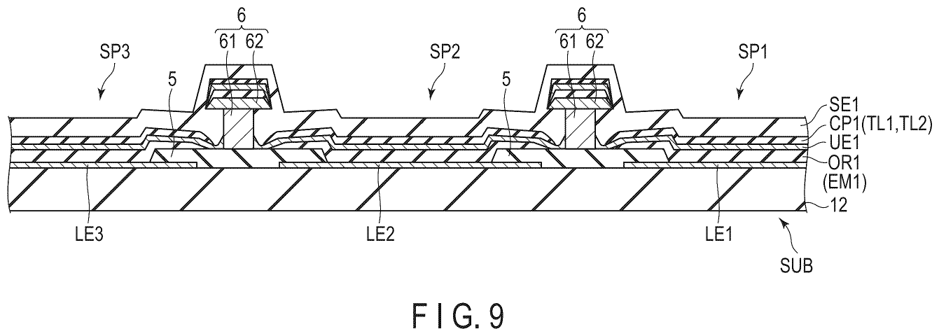

FIG. 9 shows the section of the processing substrate SUB in which the organic layer OR1, the upper electrode UE1, the cap layer CP1 and the sealing layer SE1 are formed.

The organic layer OR1, the upper electrode UE1, the cap layer CP1 and the sealing layer SE1 are formed in at least the entire display area DA and are provided in subpixels SP2 and SP3 as well as subpixel SP1. The organic layer OR1, the upper electrode UE1 and the cap layer CP1 are divided by the partition 6 having an overhang shape.

The materials which are emitted from the evaporation source when the organic layer OR1, the upper electrode UE1 and the cap layer CP1 are formed by vapor deposition are blocked by the upper portion 62. Thus, each of the organic layer OR1, the upper electrode UE1 and the cap layer CP1 is partly stacked on the upper portion 62. The organic layer OR1, upper electrode UE1 and cap layer CP1 located on the upper portion 62 are spaced apart from the organic layer OR1, upper electrode UE1 and cap layer CP1 located immediately above the lower electrode LE1.

The sealing layer SE1 covers the cap layer CP1 located immediately above the partition 6, covers the cap layer CP1 located immediately above the lower electrode LE1 and is in contact with the partition 6.

Subsequently, a resist RS patterned into a predetermined shape is formed on the sealing layer SE1 (ST14). The resist RS is formed by the resist formation device 220.

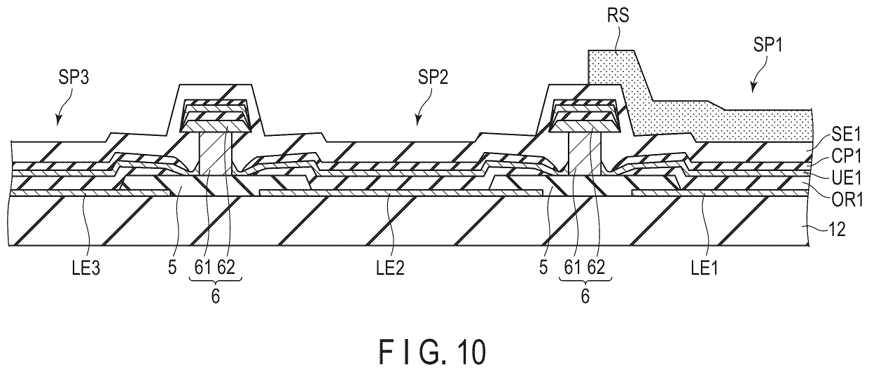

FIG. 10 shows the section of the processing substrate SUB in which the resist RS is formed.

The resist RS overlaps subpixel SP1 and part of the partition 6 around subpixel SP1.

Subsequently, patterning is performed using the resist RS as a mask (ST15). The patterning is performed by the wet etching device 230 and the dry etching device 240. The sealing layer SE1, cap layer CP1, upper electrode UE1 and organic layer OR1 exposed from the resist RS are removed in series by performing various types of etching using the resist RS as a mask.

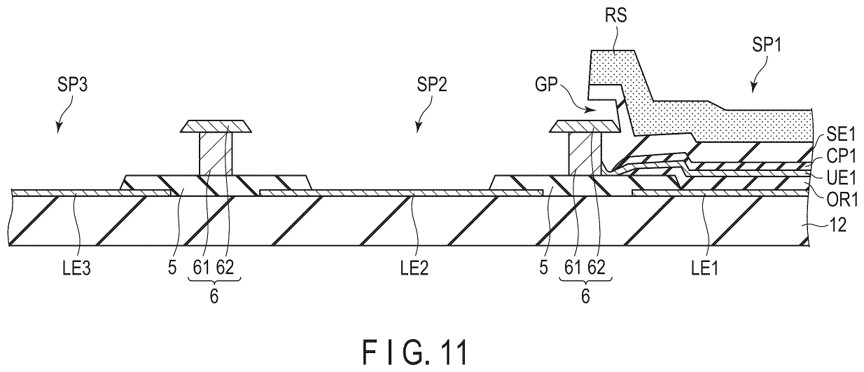

FIG. 11 shows the section of the processing substrate SUB to which patterning has been applied.

By this patterning, the lower electrode LE2 of subpixel SP2 and the lower electrode LE3 of subpixel SP3 are exposed. Further, in the example shown in the figure, the organic layer OR1, upper electrode UE1 and cap layer CP1 stacked on the partition 6 are removed at the time of patterning. Thus, the gap GP is defined between the sealing layer SE1 and the partition 6.

Subsequently, the resist RS is removed (ST16). By this process, the display element 201 is formed in subpixel SP1.

Subsequently, the display element 202 is formed. The procedure of forming the display element 202 is similar to that of forming the display element 201. Specifically, the preprocess of the processing substrate SUB in which the display element 201 is formed is performed (ST21). Subsequently, a second evaporation layer is formed on the lower electrode LE2 (ST22). The second evaporation layer has the organic layer OR2 including the light emitting layer EM2, the upper electrode UE2 and the cap layer CP2. Subsequently, the sealing layer SE2 is formed (ST23). Subsequently, a resist is formed on the sealing layer SE2 (ST24). Subsequently, patterning is performed using the resist as a mask (ST25). The sealing layer SE2, cap layer CP2, upper electrode UE2 and organic layer OR2 exposed from the resist are removed in series. Subsequently, the resist is removed (ST26).

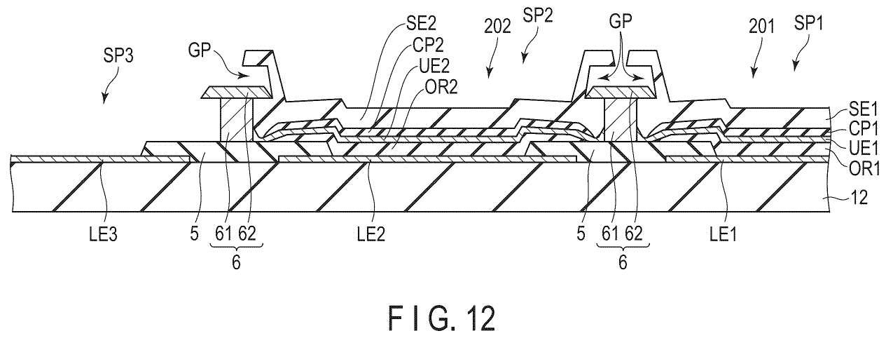

FIG. 12 shows the section of the processing substrate SUB to which patterning has been applied.

By this patterning, the display element 202 is formed in subpixel SP2, and the lower electrode LE3 of subpixel SP3 is exposed. Further, in the example shown in the figure, as the organic layer OR2, upper electrode UE2 and cap layer CP2 stacked on the partition 6 are removed at the time of patterning, the gap GP is defined between the sealing layer SE2 and the partition 6.

Subsequently, the display element 203 is formed. The procedure of forming the display element 203 is similar to that of forming the display element 201. Specifically, the preprocess of the processing substrate SUB in which the display element 201 and the display element 202 are formed is performed (ST31). Subsequently, a third evaporation layer is formed on the lower electrode LE3 (ST32). The third evaporation layer has the organic layer OR3 including the light emitting layer EM3, the upper electrode UE3 and the cap layer CP3. Subsequently, the sealing layer SE3 is formed (ST33). Subsequently, a resist is formed on the sealing layer SE3 (ST34). Subsequently, patterning is performed using the resist as a mask (ST35). The sealing layer SE3, cap layer CP3, upper electrode UE3 and organic layer OR3 exposed from the resist are removed in series. Subsequently, the resist is removed (ST36).

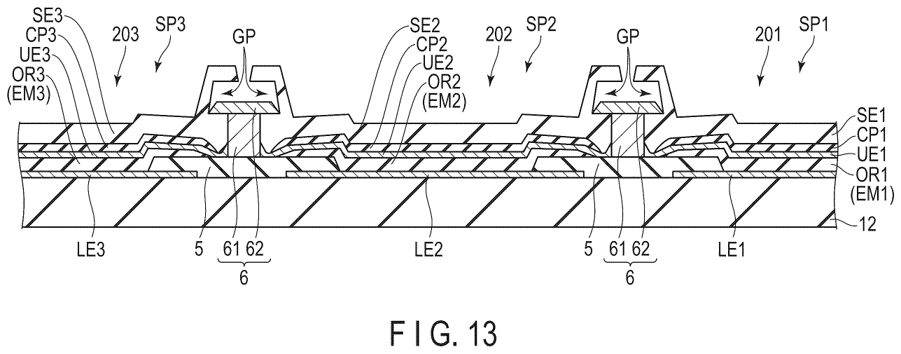

FIG. 13 shows the section of the processing substrate SUB to which patterning has been applied.

By this patterning, the display element 203 is formed in subpixel SP3. Further, in the example shown in the figure, as the organic layer OR3, upper electrode UE3 and cap layer CP3 stacked on the partition 6 are removed at the time of patterning, the gap GP is defined between the sealing layer SE3 and the partition 6.

In the manufacturing process described above, this specification assumes a case where the display element 201 is formed firstly, and the display element 202 is formed secondly, and the display element 203 is formed lastly. However, the formation order of the display elements 201, 202 and 203 is not limited to this example.

Subsequently, the resin layer 13 is formed in the resin formation device 250.

First, the processing substrate SUB is carried in the application device 251. In the application device 251, a resinous material is applied to the upper side of the sealing layers SE1, SE2 and SE3 in an air atmosphere (ST41).

Subsequently, the processing substrate SUB is carried in the drying device 252. The drying device 252 is maintained such that the pressure is lower than an air atmosphere. As the processing substrate SUB is placed in a decompressed environment, the emission of moisture from the resinous material is accelerated, and the resinous material is dried (ST42). At the same time, the gap GP is filled with the resinous material.

Subsequently, the processing substrate SUB is carried in the curing device 253. Subsequently, the resinous material is irradiated with ultraviolet rays in an air atmosphere (ST43). By the irradiation, the resinous material is cured. By this process, the resin layer 13 is formed. It should be noted that, after the resinous material is applied, the resinous material may be irradiated with ultraviolet rays by skipping the drying process (ST42).

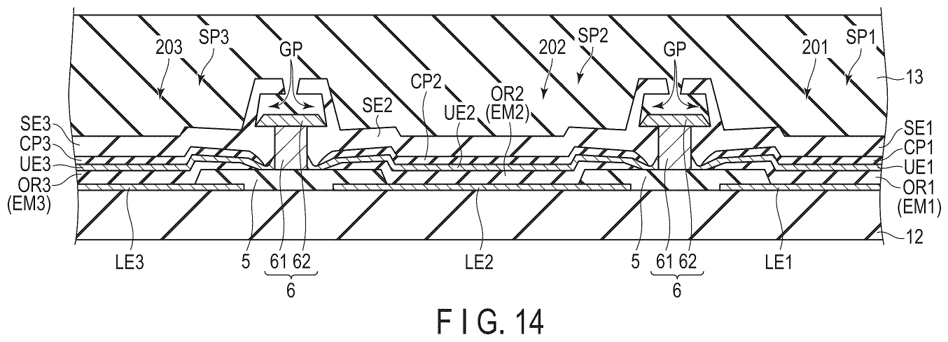

FIG. 14 shows the section of the processing substrate SUB in which the resin layer 13 is formed. In the example shown in the figure, the gap GP is filled with the resin layer 13, and no cavity is present in the gap GP.

The processing substrate SUB is carried in the heating portion 102 of the evaporation device 100. In the heating portion 102, the processing substrate SUB is heated (ST44). By this process, the moisture contained in the resin layer 13 is eliminated. It should be noted that the heating process (ST44) may be omitted.

Subsequently, the processing substrate SUB is carried in the CVD device 210. In the CVD device 210, the sealing layer 14 which covers the resin layer 13 is formed by depositing an inorganic insulating material (ST45).

Subsequently, the processing substrate SUB is carried in the resin formation device 250. In the resin formation device 250, the overcoat layer 15 is formed on the sealing layer 14 in a manner similar to that of the formation of the resin layer 13 (ST46).

Subsequently, the processing substrate SUB is carried in the dry etching device 240. In the dry etching device 240, the sealing layer 14 is patterned using the overcoat layer 15 as a mask (ST47).

Through the above process, the display device DSP is completed.

In the embodiment, the partition 6 having an overhang shape is provided in the boundaries of subpixels SP1, SP2 and SP3. This partition 6 surrounds the organic layers OR1, OR2 and OR3, upper electrodes UE1, UE2 and UE3 and cap layers CP1, CP2 and CP3 formed by vapor deposition. The display element 201 of subpixel SP1, the display element 202 of subpixel SP2 and the display element 203 of subpixel SP3 are individually divided from each other by the partition 6. These divided display elements 201, 202 and 203 are individually sealed by the sealing layers SE1, SE2 and SE3, respectively. Thus, even if a problem occurs in one of the display elements because of permeation of moisture, the diffusion of the moisture which permeated the display element to an adjacent display element is prevented.

In addition, in the structure which prevents the diffusion of moisture to an adjacent display element as described above, the tolerable moisture content of the resin layer 13 can be increased compared to a structure in which an organic layer is not divided in adjacent display elements (comparative example).

In the comparative example, when, for example, a crack is generated in a sealing layer, the moisture which entered the display element through the crack spreads over a plurality of display elements, and thus, a large number of display elements are damaged. For this reason, the moisture content should be very low regarding a resin layer which covers the sealing layer. Thus, the resin layer needs to be formed in a nitrogen atmosphere where the moisture concentration is very low or in an atmosphere of clean dry air. For example, the moisture concentration which is acceptable for an atmosphere for forming the resin layer in the comparative example is less than or equal to 100 ppm. Thus, in the comparative example, equipment for generating a nitrogen atmosphere or clean dry air is needed.

In the embodiment, a high moisture content is allowed for the resin layer 13 which covers the sealing layers SE1, SE2 and SE3. Therefore, the process of applying a resinous material to form the resin layer 13 can be performed in an air atmosphere. For example, the process of applying a resinous material can be performed in an air atmosphere of a clean room which is adjusted such that the temperature is in the range of 20° C. to 30° C., the humidity is in the range of 40% to 70%, and the oxygen concentration is greater than equal to 20%. Thus, equipment for generating an atmosphere in which the moisture concentration is very low is unnecessary. The resin layer 13 can be formed by using the device which forms the overcoat layer 15. In this manner, the manufacturing cost can be reduced. In addition, as the scale of the manufacturing device can be reduced, the installation area of the facilities can be decreased.

Further, the process of drying a resinous material under reduced pressure can be added after the resinous material is applied and before the resinous material is cured. For example, as the conditions for reduced-pressure drying, the pressure is in the range of 100 to 1000 Pa, and the time is in the range of 10 to 150 seconds. By this process, the gap GP is filled with the resinous material at the same time as the drying of the resinous material, and thus, the formation of a cavity (air bubble) in the gap GP can be prevented. In a case where the viscosity of the applied resinous material is less, and the gap GP can be sufficiently filled with the resinous material at the time of applying the resinous material, the reduced-pressure drying process may be omitted.

In a case where there is concern that the resinous material applied in an air atmosphere contains a large amount of moisture, the process of heating the processing substrate SUB may be added after forming the resin layer. For example, as the heating conditions, the temperature is in the range of 90° C. to 120° C., and the pressure is less than or equal to 1000 Pa, and the time is in the range of 3 to 60 minutes. By this process, dehydration from the resin layer 13 can be accelerated. Further, existing equipment (heating portion 102) provided in the evaporation device 100 can be used for the heating process. Therefore, there is no need to newly add a heating device. In this manner, an increase in the manufacturing cost is prevented. When the moisture content of the resinous material is sufficiently less, the heating process may be omitted.

As explained above, the embodiment can provide a display device and a manufacturing method of a display device such that the manufacturing cost can be reduced.

All of the display devices and manufacturing methods thereof that can be implemented by a person of ordinary skill in the art through arbitrary design changes to the display device and manufacturing method thereof described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing method of a display device, comprising:
preparing a processing substrate by forming a lower electrode above a substrate, forming an inorganic insulating layer having an aperture which overlaps the lower electrode, and forming a partition including a lower portion located on the inorganic insulating layer and an upper portion which is located on the lower portion and protrudes from a side surface of the lower portion;
forming an organic layer including a light emitting layer on the lower electrode in the aperture;
forming an upper electrode on the organic layer;
forming a cap layer on the upper electrode;
forming a first sealing layer which covers the cap layer and the partition; and
forming a resin layer which covers the first sealing layer, wherein
the process of forming the organic layer, the upper electrode and the cap layer is an evaporation process using the partition as a mask in a vacuum environment, and
the process of forming the resin layer includes a process of applying a resinous material in an air atmosphere.

2. The manufacturing method of claim 1, wherein
the process of forming the resin layer includes a process of drying the resinous material in an environment where a pressure is reduced compared to the air atmosphere after the process of applying the resinous material.

3. The manufacturing method of claim 2, wherein
the process of forming the resin layer includes a process of irradiating the resinous material with an ultraviolet ray in the air atmosphere after the process of drying the resinous material.

4. The manufacturing method of claim 1, wherein
the process of forming the resin layer includes a process of irradiating the resinous material with an ultraviolet ray in the air atmosphere.

5. The manufacturing method of claim 3, further comprising heating the processing substrate after forming the resin layer.

6. The manufacturing method of claim 5, further comprising:
forming a second sealing layer which covers the resin layer; and
forming an overcoat layer on the second sealing layer.

7. The manufacturing method of claim 1, wherein
the process of applying the resinous material is performed in an air atmosphere which is adjusted such that a temperature is in a range of 20° C. to 30° C., a humidity is in a range of 40% to 70%, and an oxygen concentration is greater than or equal to 20%.

8. The manufacturing method of claim 1, further comprising, before forming the resin layer,
forming a patterned resist on the first sealing layer, and
removing the first sealing layer, the cap layer, the upper electrode and the organic layer exposed from the resist in series by etching.

9. A display device comprising:
a substrate;
a lower electrode provided above the substrate;
an inorganic insulating layer having an aperture which overlaps the lower electrode;
an organic layer provided on the lower electrode in the aperture and including a light emitting layer;
an upper electrode provided on the organic layer;
a cap layer provided on the upper electrode;
a partition which has a lower portion provided on the inorganic insulating layer, being in contact with the upper electrode and formed of a conductive material, and an upper portion provided on the lower portion and protruding from a side surface of the lower portion, and surrounds the organic layer, the upper electrode and the cap layer; and
a first sealing layer which is provided on the cap layer surrounded by the partition, is in contact with the side surface of the partition and is formed of an inorganic insulating material, wherein
the first sealing layer extends to an upper side of the partition and is spaced apart from the upper portion of the partition.

10. The display device of claim 9, further comprising a resin layer which covers the first sealing layer, wherein
a gap surrounded by the upper portion and the first sealing layer is filled with the resin layer.

11. The display device of claim 10, further comprising:
a second sealing layer which covers the resin layer and is formed of an inorganic insulating material; and
an overcoat layer provided on the second sealing layer.

12. The display device of claim 9, wherein
none of the organic layer, the upper electrode and the cap layer is present between the upper portion and the first sealing layer.

13. The display device of claim 11, wherein
the resin layer and the overcoat layer are formed of a same material.

14. A manufacturing method of a display device, comprising:
preparing a processing substrate by forming a lower electrode above a substrate, forming an inorganic insulating layer having an aperture which overlaps the lower electrode, and forming a partition which includes a lower portion located on the inorganic insulating layer and an upper portion located on the lower portion and protruding from a side surface of the lower portion;
conveying the processing substrate to a first evaporation chamber, and forming an organic layer including a first light emitting layer on the lower electrode in the aperture;
conveying the processing substrate without deposition of a material for forming a second light emitting layer which is different from the first light emitting layer in a second evaporation chamber for forming the second light emitting layer;
conveying the processing substrate without deposition of a material for forming a third light emitting layer which is different from the first light emitting layer and the second light emitting layer in a third evaporation chamber for forming the third light emitting layer;
forming an upper electrode on the organic layer;
forming a cap layer on the upper electrode;
forming a first sealing layer which covers the cap layer and the partition; and
forming a resin layer which covers the first sealing layer, wherein
the process of forming the resin layer includes a process of applying a resinous material in an air atmosphere.

15. The manufacturing method of claim 14, wherein
the process of forming the resin layer includes, after the process of applying the resinous material,
a process of drying the resinous material in an environment where a pressure is reduced compared to the air atmosphere, and
a process of irradiating the resinous material with an ultraviolet ray in the air atmosphere.

16. The manufacturing method of claim 15, further comprising heating the processing substrate after forming the resin layer.

17. The manufacturing method of claim 14, further comprising, before forming the resin layer,
forming a patterned resist on the first sealing layer,
removing the first sealing layer, the cap layer, the upper electrode and the organic layer exposed from the resist in series by etching, and
removing the cap layer, the upper electrode and the organic layer located between the upper portion and the first sealing layer, wherein
a gap surrounded by the upper portion and the first sealing layer is filled with the resin layer when the resin layer is formed.

18. The manufacturing method of claim 17, further comprising:
forming a second sealing layer which covers the resin layer; and
forming an overcoat layer on the second sealing layer.

19. The manufacturing method of claim 18, wherein
the resin layer and the overcoat layer are formed by using a same material in a same device.

20. The manufacturing method of claim 18, wherein
the first sealing layer and the second sealing layer are formed by using silicon nitride in a same device.
